(19) United States
(12) Patent Application Publication
(10) Pub. No.: US 2009/0086452 A1
(43) Pub. Date: Apr. 2, 2009

(54) PRINTED CIRCUIT BOARD

(75) Inventors: CHIEN-HUNG LIU, Tu-Cheng (TW); SHOU-KUO HSU, Tu-Cheng (TW); YU-CHANG PAI, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/954,233

(22) Filed: Dec. 12, 2007

(30) Foreign Application Priority Data
Sep. 28, 2007 (CN) 200710201895.5

(51) Int. Cl. H05K 1/02

(52) U.S. Cl. 361/780; 174/255

(57) ABSTRACT

A printed circuit board (PCB) includes parallel first and second signal layers sandwiching a dielectric layer therebetween, and a differential pair having two differential traces respectively disposed within the first and second signal layers at least partially overlapping in vertical alignment. Horizontal distance between midlines of the two differential traces is less than the width of either of the two differential traces.

### BACKGROUND

1. Field of the Invention

The present invention relates to printed circuit boards (PCBs), and particularly to a PCB which can reduce time skew and common-mode noise between two differential traces of a differential pair.

2. Description of Related Art

Referring to FIG. 1, a partial cross-sectional view of a conventional PCB is illustrated. As shown, the PCB includes a differential pair 10 having two differential traces 101 and 102 disposed within a signal layer in an edge-coupled mode, and two reference layers 31 and 32 arranged at two sides of the signal layer. The differential impedance between the two differential traces 101 and 102 can be adjusted by changing the distance therebetween in the signal layer. A preferred value of the differential impedance is approximately 100 ohms.

However, the two differential traces 101 and 102 of the differential pair 10, which are disposed in an edge-coupled mode, may have two different dielectric constants, which can cause too much time skew and common-mode noise therebetween.

What is desired, therefore, is to provide a PCB which overcomes the above problems.

### SUMMARY

An embodiment of a printed circuit board (PCB) includes parallel first and second signal layers sandwiching a dielectric layer therebetween, and a differential pair having two differential traces respectively disposed within the first and second signal layers at least partially overlapping in vertical alignment. Horizontal distance between midlines of the two differential traces is less than the width of either of the two differential traces.

Other advantages and novel features of the present invention will become more apparent from the following detailed description of an embodiment when taken in conjunction with the accompanying drawings, in which:

### BRIEF DESCRIPTION OF THE DRAWINGS

FIG. 1 is a partial cross-sectional view of a conventional PCB; and

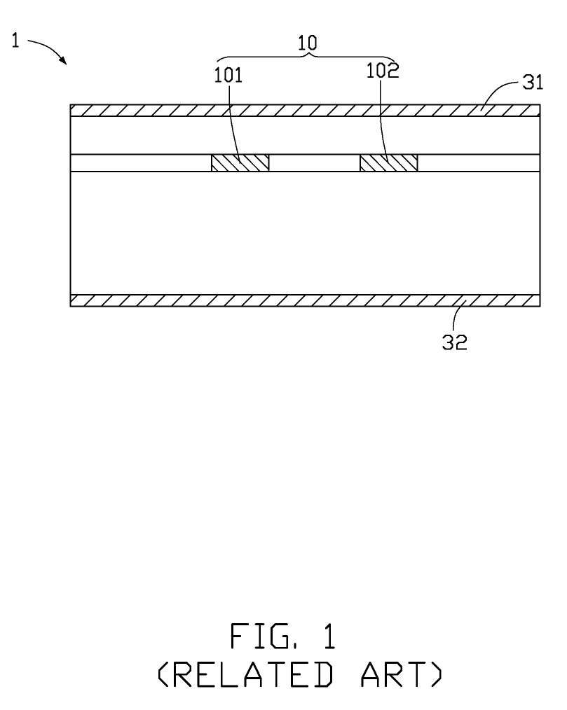

FIG. 2 is a partial cross-sectional view of a PCB in accordance with an embodiment of the present invention.

### DETAILED DESCRIPTION

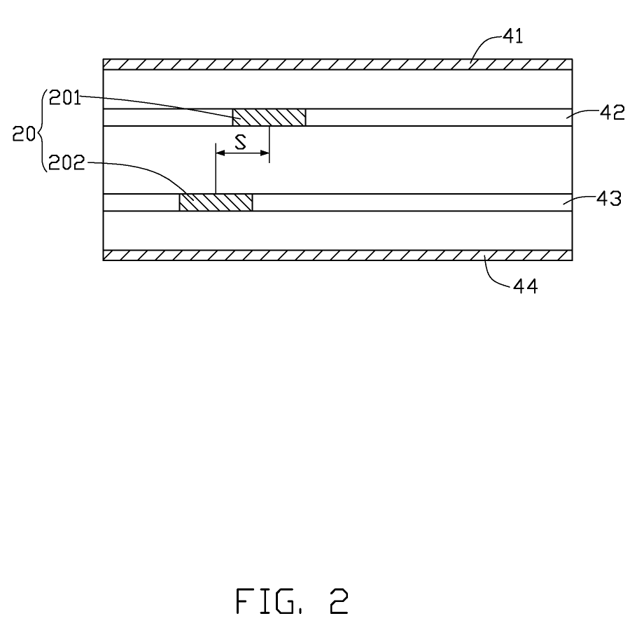

Referring to FIG. 2, a printed circuit board (PCB) in accordance with an embodiment of the present invention includes a first reference layer 41, a first signal layer 42, a second signal layer 43, and a second reference layer 44. Three dielectric layers are respectively arranged between the first reference layer 41 and the first signal layer 42, between the first signal layer 42 and the second signal layer 43, and between the second signal layer 43 and the second reference layer 44. In this embodiment, the first and second reference layers 41 and 44 are both metal.

A differential pair 20, having two differential traces 201 and 202 respectively disposed within the first and second signal layers 42 and 43, is arranged in a broadside-couple mode.

A differential impedance between the two differential traces 101 and 102 can be calculated with this formula:

$${Z}_{Diff} \approx 2 \sqrt{\frac{{L}_{11} - {L}_{12}}{{C}_{22} - {C}_{21}}}$$

Wherein, Z_{Diff} is the differential impedance between the two differential traces 101 and 102. C₂₂ and L₁₁ are respectively capacitance and inductance of the differential pair 10 to ground. C₂₁ and L₁₂ are respectively coupling capacitance and coupling inductance between the two differential traces 101 and 102.

A distance S between midlines of the two differential traces 201 and 202 can be adjusted according to need. When the distance S is increased, the area falling between where the two differential traces 101 and 102 overlap, will be reduced, thereby the capacitance C₂₂ will be reduced, and the differential impedance Z_{Diff} will be increased. Thus, the differential impedance Z_{Diff} can be adjusted by changing the distance S. In this embodiment, the distance S is approximately 4.5 mils, and the differential impedance Z_{Diff} is adjusted to approximately 99.91 ohms. When the distance S is adjusted, the distance S must be less than the width of either of the two differential traces 201 and 202.

Because the differential impedance Z_{Diff} can be adjusted by changing the distance S, and the dielectric layer between the first and second signal layers 42 and 43 can reduce electromagnetic interference therebetween, time skew and common-mode noise between the two differential traces 201 and 202 of the differential pair 20 is minimized.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A printed circuit board (PCB) comprising:
parallel first and second signal layers sandwiching a dielectric layer therebetween; and
a differential pair having a first differential trace dispoed within the first signal layer and a second differential trace disposed with the second signal layer, the two differential traces at least partially vertically overlapping with each other, and wherein a horizontal distance between midlines of the two differential traces is less than the width of either differential trace.

2. The PCB as claimed in claim 1, wherein when the horizontal distance between the midlines of the two differential traces is approximately 4.5 mils, a differential impedance between the two differential traces is calculated with this formula:
$${Z}_{Diff} = 2 \sqrt{\frac{{L}_{11} - {L}_{12}}{{C}_{22} - {C}_{21}}}$$
wherein, Z_{Diff} is the differential impedance between the two differential traces, Cₙ and L₁₁ are respectively coupling capacitance and inductance of the differential pair to ground, C₂₁ and L₁₂ are respectively coupling capacitance and coupling inductance between the two differential traces, the differential impedance Z_{Diff} is approximately 99.91 ohms.

3. The PCB as claimed in claim 1, further comprising a first reference layer, a second reference layer, the first dielectric layer arranged between the first reference layer and the first signal layer, and the second dielectic layer arranged between the second signal layer and the second reference layer.

4. The PCB as claimed in claim 3, wherein the first and second reference layers are both metal.

5. A printed circuit board (PCB) comprising:
a first signal layer extending along a first direction;
a second signal layer parallel to the first signal layer, and sandwiching a dielectric layer with the first signal layer; and
a differential pair having a first differential trace disposed in the first signal layer, and a second differential trace disposed in the second signal layer, the first and second differential traces at least partially overlapping in a second direction perpendicular to the first direction, wherein the first direction distance between midlines of the first and second differential traces of the differential pair is less than the width of either of the first and second differential trances.

6. The PUB as claimed in claim 5, wherein when the horizontal distance between the midlines of the first end second differential traces is approximately 4.5 mils, a differential impedance between the first and second differential traces is calculated with this formula:
$${Z}_{Diff} = 2 \sqrt{\frac{{L}_{11} - {L}_{12}}{{C}_{22} - {C}_{21}}}$$
wherein, Z_{Diff} is the differential impedance between the first and second differential traces, C₂₂ and L₁₁ are respectively capacitance and inductance of the differential pair to ground, C₂₁, and L₁₂ are respectively coupling capacitance and coupling inductance between the first and second differential traces, the differential impedance Z_{Diff} is approximately 99.91 ohms.

7. The PCB as claimed in claim 5, further comprising a first reference layer, a second reference layer, a dielectric layer arranged between the first reference layer and the first signal layer, and a dielectric layer arranged between the second signal layer and the second reference layer.

8. The PCB as claimed in claim 7, wherein the first and second reference layers are both metal.
